(19) United States
(12) Patent Application Publication
(10) Pub. No.: US 2017/0371073 A1
(43) Pub. Date: Dec. 28, 2017

(54) PREDICTION APPARATUS, PREDICTION METHOD, AND NON-TRANSITORY STORAGE MEDIUM

(71) Applicant: NEC Corporation, Tokyo (JP)

(72) Inventors: Katsuya SUZUKI, Tokyo (JP); Kosuke HOMMA, Tokyo (JP); Koji KUDO, Tokyo (JP)

(73) Assignee: NEC Corporation, Tokyo (JP)

(21) Appl. No.: 15/543,435

(22) PCT Filed: Nov. 18, 2015
(86) PCT No.: PCT/JP2015/082353

§ 371 Date: Jul. 13, 2017

(30) Foreign Application Priority Data
Jan. 30, 2015 (JP) 2015-017107

(51) Int. Cl. G01W 1/00; G01R 21/133; G01J 1/42; G01P 5/00; G06N 99/00; G06N 7/00

(52) U.S. Cl. CPC G01W 1/00; G06N 99/005; G06N 7/005; G01J 1/42; G01P 5/00; G01R 21/133; G01J 2001/4266

(57) ABSTRACT

An object of the present invention is to improve the accuracy of prediction in a technique for predicting natural energy power generation amount, solar radiation amount or wind speed by using a statistical method based on machine learning. In order to achieve this object, provided is a prediction apparatus (10) including a feature value extraction unit (13) that extracts a feature value being a variation in time series from meteorological data from m (m is 2 or more) hours before a target time to the target time, and an estimation unit (first estimation unit (14)) that estimates a natural energy power generation amount, a solar radiation amount, or a wind speed at the target time based on the feature values over plural days.

### TECHNICAL FIELD

The present invention relates to a prediction apparatus, a prediction method, and a program, and more specifically, relates to a prediction apparatus, a prediction method, and a program, which predict a natural energy power generation amount, a solar radiation amount, and/or a wind speed.

### BACKGROUND ART

Patent Documents 1 to 3, and Non-Patent Document 1 disclose a technique for predicting a photovoltaic power generation amount, or a solar radiation amount from meteorological data by using a statistical method based on machine learning.

### RELATED DOCUMENT

### Patent Document

[Patent Document 1] Japanese Patent Application Publication No. 9-215192
[Patent Document 2] Japanese Patent No. 3984604
[Patent Document 3] Japanese Patent No. 5339317

### Non-Patent Document

[Non-Patent Document 1] Joao Gari da Silva Fonseca Junior, Takashi Oozeki, Takumi Takashima, and Kazuhiko Ogimoto, Analysis of the Use of Support Vector Regression and Neural Networks to Forecast Insolation for 25 Locations in Japan, Solar World Congress 2011 Proceedings, Germany, International Solar Energy Society, 2011, pp. 4128-4135.

### SUMMARY OF THE INVENTION

### Technical Problem

In the case of the techniques disclosed in Patent Documents 1 to 3, and Non-Patent Document 1, accuracy of prediction was not sufficient. An object of the present invention is to improve the accuracy of prediction in a technique for predicting a natural energy power generation amount, a solar radiation amount, and/or a wind speed by using a statistical method based on machine learning.

### Solution to Problem

According to the present invention, there is provided a prediction apparatus including a feature value extraction unit that extracts a feature value being a variation in time series from meteorological data from m (m is 2 or more) hours before a target time to the target time, and an estimation unit that estimates a natural energy power generation amount, a solar radiation amount, or a wind speed at the target time based on the feature values over plural days.

Further, according to the present invention, there is provided a prediction method executed by a computer, the method including a feature value extraction step of extracting a feature value being a variation in time series from meteorological data from m (m is 2 or more) hours before a target time to the target time, and an estimation step of estimating a natural energy power generation amount, a solar radiation amount, or a wind speed at the target time based on the feature values over plural days.

Further, according to the present invention, there is provided a program causing a computer to function as a feature value extraction unit that extracts a feature value being a variation in time series from meteorological data from m (m is 2 or more) hours before a target time to the target time, and an estimation unit that estimates a natural energy power generation amount, a solar radiation amount, or a wind speed at the target time based on the feature values over plural days.

Further, according to the present invention, there is provided a prediction apparatus including a feature value extraction unit that extracts a feature value being a variation in time series from meteorological data from m (m is 2 or more) hours before a target time to the target time, and an estimation unit that estimates a natural energy power generation amount, a solar radiation amount, or a wind speed at the target time based on the feature value.

Further, according to the present invention, there is provided a prediction apparatus including a prediction expression acquisition unit that acquires a prediction expression for predicting a natural energy power generation amount, a solar radiation amount, or a wind speed at a target time which is generated by machine learning based on training data over plural days with a feature value extracted from meteorological data from m (m is 2 or more) hours before the target time to the target time as an explanatory variable, and the natural energy power generation amount, the solar radiation amount, or the wind speed at the target time as an objective variable, a meteorological data acquisition unit that acquires meteorological data up to the target time on a prediction target day, a feature value extraction unit that extracts the feature value from meteorological data from m hours before the target time to the target time on the prediction target day, and a first estimation unit that estimates a natural energy power generation amount, a solar radiation amount, or a wind speed at the target time on the prediction target day, based on the prediction expression acquired by the prediction expression acquisition unit and the feature value extracted by the feature value extraction unit.

### Advantageous Effects of Invention

According to the present invention, it is possible to improve the accuracy of prediction in a technique for predicting a photovoltaic power generation amount, or a solar radiation amount by using a statistical method based on machine learning.

### BRIEF DESCRIPTION OF THE DRAWINGS

The foregoing and other objects, features, and advantages will become more apparent from the following description of preferred exemplary embodiments and the accompanying drawings.

FIG. 1 shows conceptually an example of a hardware configuration of an apparatus of the present exemplary embodiment.

FIG. 2 shows an example of a functional block diagram of a prediction apparatus of the present exemplary embodiment.

FIG. 3 shows an example of a functional block diagram of a prediction expression acquisition unit of the present exemplary embodiment.

FIG. 4 schematically shows an example of past data used by the prediction apparatus of the present exemplary embodiment.

FIG. 5 shows an overview of the present exemplary embodiment.

FIG. 6 shows another example of a functional block diagram of the prediction apparatus of the present exemplary embodiment.

FIG. 7 shows an example of information displayed by the prediction apparatus of the present exemplary embodiment.

FIG. 8 shows another example of information displayed by the prediction apparatus of the present exemplary embodiment.

FIG. 9 shows still another example of information displayed by the prediction apparatus of the present exemplary embodiment.

FIG. 10 shows still another example of a functional block diagram of the prediction apparatus of the present exemplary embodiment.

FIG. 11 shows a verification result of the prediction apparatus of the present exemplary embodiment.

FIG. 12 shows still another example of a functional block diagram of the prediction apparatus of the present exemplary embodiment.

### DESCRIPTION OF EXEMPLARY EMBODIMENTS

First, an example of a hardware configuration of an apparatus of the present exemplary embodiment will be described. Each unit included in the apparatus of the present exemplary embodiment is realized by any combination of hardware and software of any computer, mainly using a central processing unit (CPU), a memory, a program to be loaded into the memory, and a storage unit such as a hard disk storing the program (can store programs installed in advance in the stage of shipping the apparatus, and also store programs downloaded from a storage medium such as a compact disc (CD) or a server on the Internet), and a network connection interface. Those skilled in the art will understand that there are various modifications in the realization methods and apparatuses.

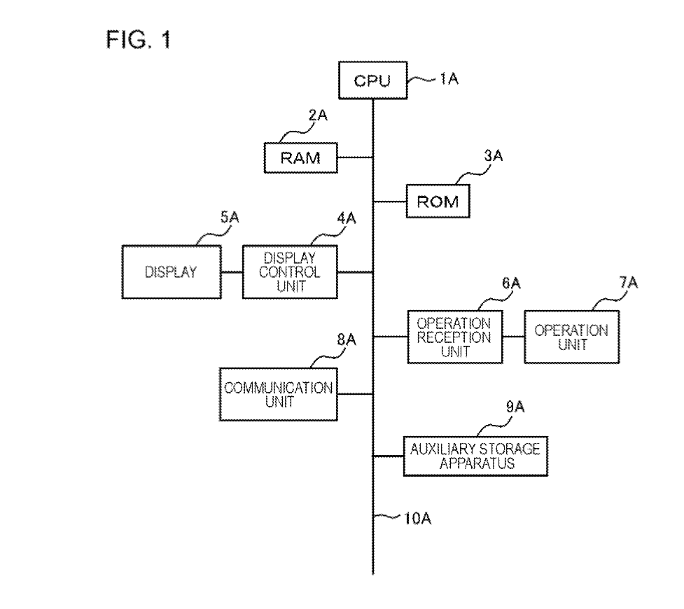

FIG. 1 shows conceptually an example of a hardware configuration of an apparatus of the present exemplary embodiment. As shown in the drawing, the apparatus of the present exemplary embodiment includes for example, a CPU 1A, a random access memory (RAM) 2A, a read only memory (ROM) 3A, a display control unit 4A, a display 5A, an operation reception unit 6A, an operation unit 7A, a communication unit 8A, an auxiliary storage apparatus 9A, and the like, which are connected through a bus 10A with each other. Note that, although not shown, other elements such as an input and output interface, a microphone, or a speaker connected to an external apparatus by wires may be provided.

The CPU 1A controls each element and the entire computer of the apparatus. The ROM 3A includes an area for storing programs for operating the computer, various application programs, various setting data to be used when these programs operate, or the like. The RAM 2A includes an area for temporarily storing data, such as a work area for a program to operate. The auxiliary storage apparatus 9A is for example, a hard disc drive (HDD), and can store a large amount of data.

The display 5A is for example, a display apparatus (a light emitting diode (LED) display, a liquid crystal display, an organic electro luminescence (EL) display, or the like). The display 5A may be a touch panel display integrated with a touch pad. The display control unit 4A reads the data stored in a video RAM (VRAM) to perform a predetermined process on the read data, and sends it to the display 5A to display various screens. The operation reception unit 6A receives various operations through the operation unit 7A. The operation unit 7A includes an operation key, an operation button, a switch, a jog dial, a touch panel display, a keyboard, and the like. The communication unit 8A is connected to a network such as the Internet or a local area network (LAN) in a wired and/or wireless manner, and communicates with other electronic apparatuses.

Hereinafter, the present exemplary embodiment will be described. Note that, the functional block diagram used in the description of the following exemplary embodiment shows blocks of functional units rather than configurations of hardware units. These drawings show that each apparatus is constituted by a single device, but means of constituting each apparatus is not limited to this. That is, it may be a physically separated configuration or a logically divided configuration. Note that, the same reference numerals may be attached to the same configuration components, and the description thereof will not be repeated.

### First Exemplary Embodiment

The prediction apparatus 10 of the present exemplary embodiment predicts a natural energy power generation amount, a solar radiation amount, or a wind speed at a target time on a prediction target day, by using a prediction expression which is generated by machine learning based on training data over plural days with a feature value extracted from meteorological data from m (m is 2 or more) hours before the target time to the target time as an explanatory variable, and a natural energy power generation amount, a solar radiation amount, or a wind speed at the target time as an objective variable.

The natural energy power generation amount means the power amount generated by power generation using natural energy. As such a power generation method, power generation using solar light, power generation using wind power, and the like are conceivable. The details of the present exemplary embodiment will be described below.

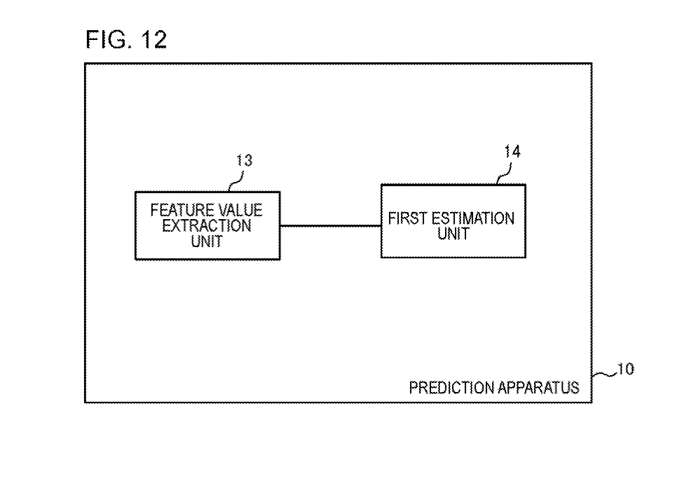

FIG. 12 shows an example of a functional block diagram of the prediction apparatus 10 of the present exemplary embodiment. As illustrated, the prediction apparatus 10 includes a feature value extraction unit 13, and a first estimation unit 14. The feature value extraction unit 13 extracts a feature value being a variation in time series from meteorological data from m (m is 2 or more) hours before a target time to the target time. The first estimation unit 14 estimates a natural energy power generation amount, a solar radiation amount, or a wind speed at the target time based on the feature values over plural days. Note that, the first estimation unit 14 may perform estimation by using a prediction expression for performing prediction with the feature value extracted from meteorological data up to the target time as an explanatory variable, and the natural energy power generation amount, the solar radiation amount, or the wind speed at the target time as an objective variable. Further, the first estimation unit 14 may perform estimation by using a prediction expression based on training data over plural days including a combination of the explanatory variable and the objective variable.

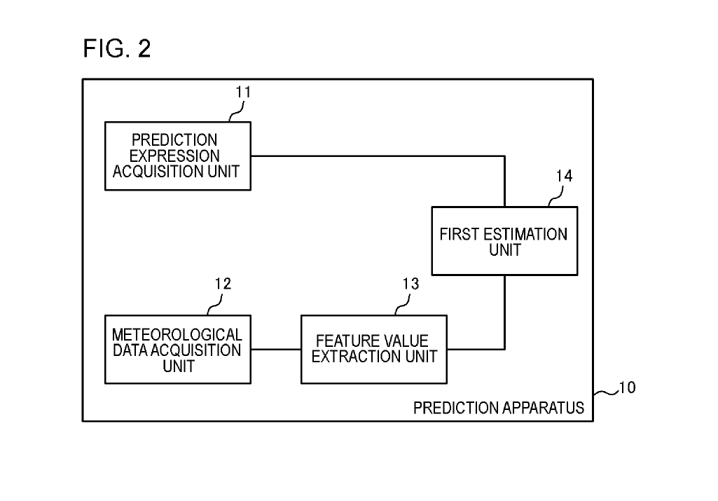

FIG. 2 shows another example of a functional block diagram of the prediction apparatus 10 of the present exemplary embodiment. As illustrated, the prediction apparatus 10 includes a prediction expression acquisition unit 11, a meteorological data acquisition unit 12, a feature value extraction unit 13, and a first estimation unit 14. Each unit will be described below.

The prediction expression acquisition unit 11 acquires a prediction expression for predicting the natural energy power generation amount, the solar radiation amount, or the wind speed of the target time. The prediction expression is generated by machine learning based on training data over plural days with a feature value extracted from meteorological data from m hours before a target time to the target time as an explanatory variable, and the natural energy power generation amount, the solar radiation amount, or the wind speed at the target time as an objective variable. The prediction expression acquisition unit 11 may generate such a prediction expression, or may acquire it from other external apparatuses communicable with the prediction apparatus 10 by wired and/or wireless communication.

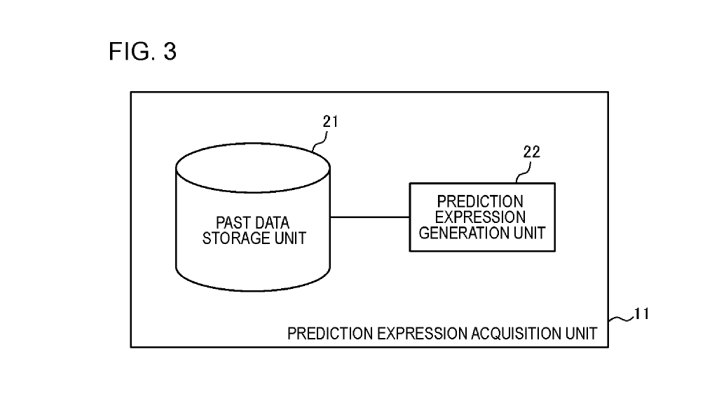

An example of a functional block diagram of the prediction expression acquisition unit 11 of the exemplary embodiment that generates a prediction expression is shown in FIG. 3. The shown prediction expression acquisition unit 11 includes a past data storage unit 21, and a prediction expression generation unit 22. Note that, in a case where the prediction expression acquisition unit 11 acquires a prediction expression from an external apparatus, the external apparatus includes the past data storage unit 21, and the prediction expression generation unit 22.

The past data storage unit 21 stores, for each date and each time in the past (every predetermined time on a predetermined day), past data in which an actual value or a prediction value (a prediction value announced at a predetermined timing before each time) of meteorological data, the actual values of a natural energy power generation amount, a solar radiation amount and/or a wind speed, and attribute values indicating attributes of the values are associated with each other. The past data storage unit 21 stores past data of plural days (example: 30 days, 60 days, 1 year, 3 years, or the like).

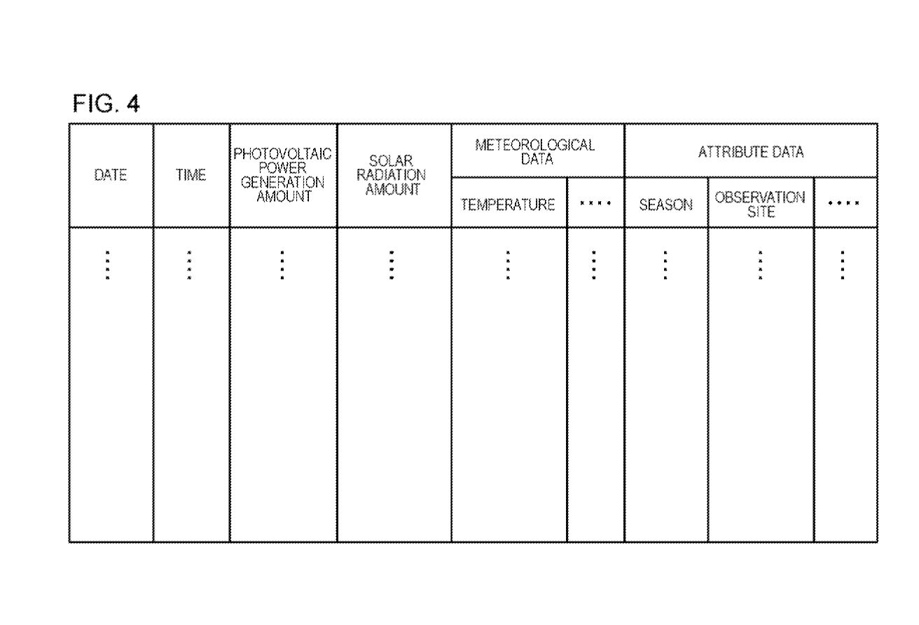

FIG. 4 schematically shows an example of past data stored by the past data storage unit 21. In the shown past data, date, time, a photovoltaic power generation amount, a solar radiation amount, meteorological data, and attribute data are associated with each other. Although not shown, the actual value of a wind speed and/or the actual value of a wind power generation amount may further be associated.

The past data includes plural data accumulated at predetermined time intervals. The time interval of data varies, and can be arbitrarily selected from every 5 minutes, every 15 minutes, every 30 minutes, every hour, and the like. Note that, the past data may also be accumulated for each observation site. That is, the past data may be accumulated at predetermined time intervals for each observation site.

In the fields of photovoltaic power generation amount and the solar radiation amount, the actual values of the accumulated amount within a predetermined time specified based on the associated date and time are entered. For example, the accumulated amount for M minutes centering round the associated date and time (M is, for example, 5, 15, 30, 60, or the like), or the accumulated amount from the associated date and time to M minutes after thereof is considered, but it is not limited thereto. In a case where actual data is accumulated for each observation site, the actual value of a solar radiation amount at each observation site, and the actual value of a photovoltaic power generation amount generated by a photovoltaic power generation apparatus installed at each observation site are entered in the fields of the photovoltaic power generation amount and the solar radiation amount.

Although not shown in the drawings, in a case of having a field of wind power generation, similarly, the actual value of the accumulated amount within a predetermined time specified based on the associated date and time is entered. In the field of a wind speed, the actual value at the associated date and time or a statistical value (an average value, a maximum value, a mode, a median value, a minimum value, or the like) of the actual values within a predetermined time specified based on the associated date and time is entered.

In the field of meteorological data, the actual value at the associated date and time is entered. Note that, in a case where the meteorological data measured exactly at the date and time of past data does not exist for reasons such as the time interval of past data and the sampling interval of meteorological data being different, meteorological data measured at the timing closest to the date and time may be used. A statistical value (an average value, a maximum value, a mode, a median value, a minimum value, or the like) of the actual values within a predetermined time specified based on the associated date and time may be entered in the field of meteorological data. Further, in the field of meteorological data, a prediction value announced at a predetermined timing earlier than the associated time may be entered, instead of the actual value. The prediction value corresponds to the value of the weather forecast announced at the previous day or the like.

The meteorological data includes data of at least one of items affecting a natural energy power generation amount, a solar radiation amount, and a wind speed. For example, items such as temperature, humidity, wind direction, wind speed, precipitation, weather, an upper cloud amount, a middle cloud amount, a lower cloud amount, a total cloud amount, a surface pressure, a sea level pressure, and a solar radiation amount are considered for the meteorological data, but the meteorological data is not limited thereto. In a case where actual data is accumulated for each observation site, the actual value or the prediction value of each observation site is entered in the field of meteorological data.

A value indicating the attribute of each data is entered in the field of attribute data. The attribute data includes data of at least one of items affecting a natural energy power generation amount, a solar radiation amount, and a wind speed. For example, the observation site, the season of the observation date, or the like may be considered for the attribute data, but the attribute data is not limited thereto. The observation site may be indicated by a city name, may be indicated by latitude and longitude, or may be indicated in other manners.

Returning to FIG. 3, the prediction expression generation unit 22 generates a prediction expression for predicting the natural energy power generation amount, the solar radiation amount, or the wind speed at the target time, based on the past data stored in the past data storage unit 21. Specifically, the prediction expression generation unit 22 generates a prediction expression, by machine learning based on training data over plural days with a feature value extracted from meteorological data from m (m is 2 or more) hours before a target time to the target time as an explanatory variable, and the natural energy power generation amount, the solar radiation amount, or the wind speed at the target time as an objective variable.

The feature value indicates the feature of a variation of meteorological data in time series within a period of time from m hours before a target time to the target time, there are various algorithms for extracting a feature value. For example, a one-dimensional array or a multi-dimensional array in which values of predetermined one or plural items (meteorological data) within the period of time are arranged in time series may be used as a feature value. Alternatively, data is plotted on a graph representing the value of a predetermined item (meteorological data) on one axis and time on the other axis, and from the shape of the obtained waveform, any feature value indicating the variation may be extracted. Further, feature values may be extracted from plural items (meteorological data) by the method (shape of waveform) and an array in which the feature values are arranged in the predetermined order of items may be used as a feature value.

As a method of machine learning, any method such as multiple regression, a neural network, a support vector machine, or the like may be adopted.

The lower limit of the value of m is 2, preferably 5, and more preferably 9. As described in the following example, by doing so, the accuracy of prediction of a natural energy power generation amount, a solar radiation amount, or a wind speed can sufficiently be improved. The upper limit of the value of m is, for example, 20, and is preferably 13. As shown in the following example, in a case where the value of m is a predetermined value or less, the greater the value of m, the higher the accuracy of prediction. However, if the value of m exceeds the predetermined value, the accuracy of the prediction is nearly flat, making it impossible to obtain large changes. By setting the upper limit of m as described above, it is possible to reduce the processing load on the computer by reducing the amount of data to be processed while realizing sufficient accuracy of prediction.

The prediction expression generation unit 22 may generate plural prediction expressions respectively corresponding to plural target times different from each other.

The meteorological data acquisition unit 12 acquires meteorological data (time series data) up to a target time on a prediction target day. The meteorological data acquisition unit 12 acquires, at least, meteorological data from m hours before the target time to the target time on the prediction target day. For example, the meteorological data acquisition unit 12 may acquire the meteorological data by communicating with the external apparatus through wired and/or wireless communication. The meteorological data acquisition unit 12 may acquire the meteorological data for each observation site.

The meteorological data acquired by the meteorological data acquisition unit 12 may be an actual value or a prediction value, or may be a mixture thereof. There may be cases where some or all of the actual values of the meteorological data are not published yet when the meteorological data acquisition unit 12 acquires meteorological data from m hours before the target time to the target time on the prediction target day. When all the actual values are not published, the meteorological data acquisition unit 12 acquires prediction values as the meteorological data from m hours before the target time to the target time on the prediction target day. On the other hand, when some actual values are published and the other actual values are not published, the meteorological data acquisition unit 12 may acquire the published actual values, and acquire prediction values in time zones when the actual values are not published. In addition, in a case where some actual values are published and the other actual values are not published, the meteorological data acquisition unit 12 may acquire prediction values in all time zones.

The feature value extraction unit 13 performs a predetermined process, based on the meteorological data acquired by the meteorological data acquisition unit 12. Specifically, the feature value extraction unit 13 extracts a feature value from meteorological data from m hours before the target time to the target time on a prediction target day. The feature value extracted by the feature value extraction unit 13 is feature value of the same type as that of the feature value used as the explanatory variable in the generation of the prediction expression acquired by the prediction expression acquisition unit 11.

The first estimation unit 14 estimates a natural energy power generation amount, a solar radiation amount, or a wind speed at the target time on the prediction target day, based on the prediction expression acquired by the prediction expression acquisition unit 11 and the feature value extracted by the feature value extraction unit 13. That is, the first estimation unit 14 inputs the feature value extracted by the feature value extraction unit 13 to the prediction expression acquired by the prediction expression acquisition unit 11, and thus obtains an estimated value (output) of a natural energy power generation amount, a solar radiation amount, or a wind speed at the target time on the prediction target day. Note that, in a case of obtaining an estimated value of the solar radiation amount, thereafter, the first estimation unit 14 may calculate the photovoltaic power generation amount by multiplying the estimated value of the solar radiation amount by a conversion coefficient. In addition, in a case of obtaining the estimated value of a wind speed, the first estimation unit 14 may input the estimated value to a predetermined expression to calculate the wind power generation amount. It is known that the wind power generation amount is proportional to the cube of a rotor area (specified by the user in advance) or a wind speed (estimated value).

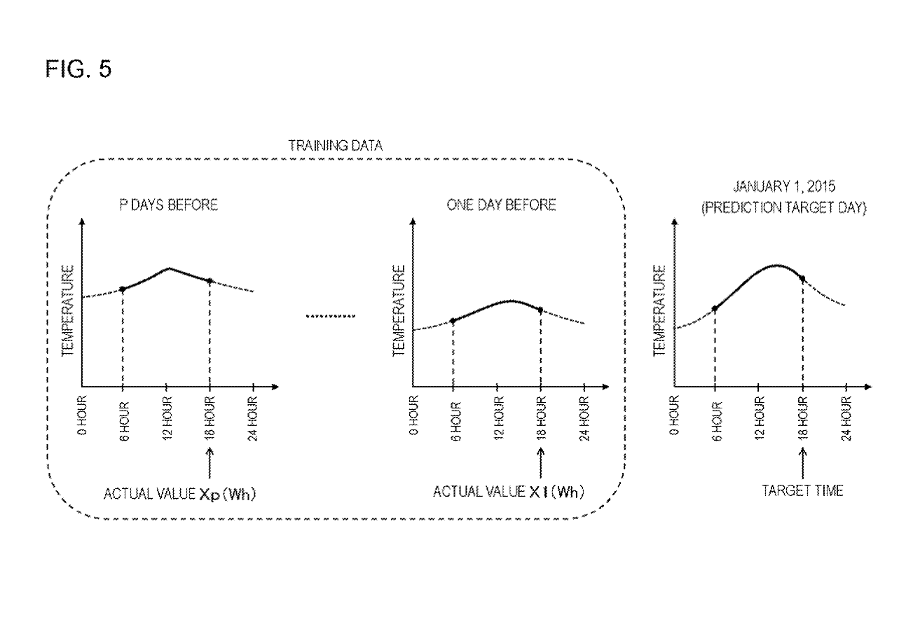

Here, the concept of processes by the prediction apparatus 10 will be described using the specific example shown in FIG. 5. For example, the prediction target day is Jan. 1, 2015, the target time is 18 o'clock, and the value of m is 12. In this case, the time m hours before the target time is 6 o'clock.

FIG. 5 shows temperature data as an example of meteorological data. In the case of the example, a prediction expression is generated using data for any plural days (in the case of the drawing, p days) before Jan. 1, 2015 (prediction target day) as training data. Specifically, the feature value extracted from meteorological data from 6 o'clock to 18 o'clock on each day is an explanatory variable. The natural energy power generation amount, the solar radiation amount, or the wind speed (in the case of the drawing, the natural energy power generation amount) at 18 o'clock on each day is an objective variable. The prediction expression acquisition unit 11 acquires a prediction expression obtained by machine learning based on training data over plural days including a combination of the explanatory variable and the objective variable. The prediction expression is an expression for predicting the natural energy power generation amount, the solar radiation amount, or the wind speed at 18 o'clock on any day.

The meteorological data acquisition unit 12 acquires at least, meteorological data from 6 o'clock to 18 o'clock on Jan. 1, 2015 (prediction target day). The meteorological data may be a prediction value, or may be a mixture of an actual value and a prediction value. As an example of the mixed one, for example, the meteorological data is an actual value from 6 o'clock to 12 o'clock, and is a prediction value thereafter.

The feature value extraction unit 13 extracts a predetermined feature value from meteorological data from 6 o'clock to 18 o'clock on Jan. 1, 2015 (prediction target day) acquired by the meteorological data acquisition unit 12. The feature value represents the variation in time series of meteorological data within a period of time from 6 o'clock to 18 o'clock on Jan. 1, 2015 (prediction target day).

The first estimation unit 14 predicts a natural energy power generation amount, a solar radiation amount, or a wind speed at 18 o'clock on Jan. 1, 2015 (prediction target day), based on the prediction expression acquired by the prediction expression acquisition unit 11 as described above and the feature value extracted by the feature value extraction unit as described above.

By changing the target time and repeating the above process, prediction of a natural energy power generation amount, a solar radiation amount, or a wind speed throughout the day of Jan. 1, 2015 (prediction target day) can be obtained.

Next, the advantageous effect of the present exemplary embodiment will be described. The prediction apparatus 10 of the present exemplary embodiment estimates the natural energy power generation amount, the solar radiation amount, or the wind speed at the target time, based on the feature of the variation of the meteorological data from predetermined hours (m hours) before the target time to the target time. As described in the following example, according to such a present exemplary embodiment, the accuracy of estimation of a natural energy power generation amount, a solar radiation amount, or a wind speed can be improved. The prediction apparatus 10 of the present exemplary embodiment can generate a prediction expression, by machine learning based on training data over plural days. Therefore, it is possible to generate a prediction expression with high accuracy.

### Second Exemplary Embodiment

The present exemplary embodiment is different from the first exemplary embodiment in that an estimation expression is generated by machine learning selectively using the past data which is similar to a prediction target in which at least one of a prediction target day and a prediction target point is specified, at a predetermined level or more. This will be described in detail below.

An example of the functional block diagram of the present exemplary embodiment is shown in FIG. 2, like the first exemplary embodiment. As illustrated, the prediction apparatus 10 of the present exemplary embodiment includes a prediction expression acquisition unit 11, a meteorological data acquisition unit 12, a feature value extraction unit 13, and a first estimation unit 14. Hereinafter, a difference from the first exemplary embodiment will be described.

The prediction expression acquisition unit 11 acquires a prediction expression generated based on training data having a predetermined attribute similar to that of a prediction target in which at least one of a prediction target day and a prediction target point is specified, at a predetermined level or more. Hereinafter, a process of generating such a prediction expression will be described.

First, the prediction expression generation unit acquires the attribute value of the prediction target. As described above, at least one of the prediction target day and the prediction target point is specified for the prediction target. For example, the month of a prediction target, the season of a prediction target day, the prediction value of meteorological data of a prediction target day, the prediction target point, or the like may be acquired as the attribute value of the prediction target.

Thereafter, the prediction expression generation unit 22 extracts data having a predetermined attribute similar to that of the prediction target, at a predetermined level or more, from the past data stored in the past data storage unit 21. For example, data of which a prediction target point (observation site) matches, or data of which the difference from the prediction target point (distance) is equal to or less than a predetermined value may be extracted. In addition, data of which the season or the month matches may be extracted. In addition, data of which the value of a predetermined item (meteorological data) at a predetermined time matches, or data of which the difference in value of the predetermined item is equal to or less than a predetermined value may be extracted (comparison between the prediction value of a prediction target and the actual value of past data). In addition, data satisfying the condition obtained by combining these conditions with a predetermined logical expression may be extracted. Alternatively, a similarity may be calculated using any method of calculating similarity and data having a similarity of a predetermined level or higher may be extracted.

After that, the prediction expression generation unit 22 generates a prediction expression by machine learning with the extracted data as training data.

The meteorological data acquisition unit 12 acquires meteorological data of a prediction target up to a target time. The feature value extraction unit 13 extracts a feature value from meteorological data. The first estimation unit 14 estimates a natural energy power generation amount, a solar radiation amount, or a wind speed of the prediction target at the target time, based on the feature value and the prediction expression acquired by the prediction expression acquisition unit 11.

According to the present exemplary embodiment, the prediction apparatus 10 can use a prediction expression generated by selectively using as training data, past data having a predetermined attribute similar to that of a prediction target, at a predetermined level or more, for estimation of a natural energy power generation amount, a solar radiation amount, or a wind speed of a prediction target at a target time.

For example, in a case of estimating a natural energy power generation amount, a solar radiation amount, or a wind speed at a first observation site, the prediction apparatus 10 can estimate the natural energy power generation amount, the solar radiation amount, or the wind speed, based on the estimation expression generated by selectively using the past data of a first observation site as the training data.

In a case of estimating a natural energy power generation amount, a solar radiation amount, or a wind speed at any day of October, the prediction apparatus 10 can estimate the natural energy power generation amount, the solar radiation amount, or the wind speed, based on the estimation expression generated by selectively using the past data of October as the training data.

Further, in a case of estimating the natural energy power generation amount, the solar radiation amount, or the wind speed on the day (prediction target day) of which a predicted temperature (maximum temperature, lowest temperature, or the like) is M° C., the prediction apparatus 10 estimates the natural energy power generation amount, the solar radiation amount, or the wind speed, based on the estimation expression generated by selectively using as training data, the past data of which an temperature (the actual value of maximum temperature, lowest temperature, or the like) is similar to the predicted temperature, at a predetermined level or more.

According to the prediction apparatus 10 of the present exemplary embodiment, the accuracy of estimation of a natural energy power generation amount, a solar radiation amount, or a wind speed is improved.

### Third Exemplary Embodiment

The prediction apparatus 10 of the present exemplary embodiment is different from the first and second exemplary embodiments in that the value of m is variable. This will be described in detail below.

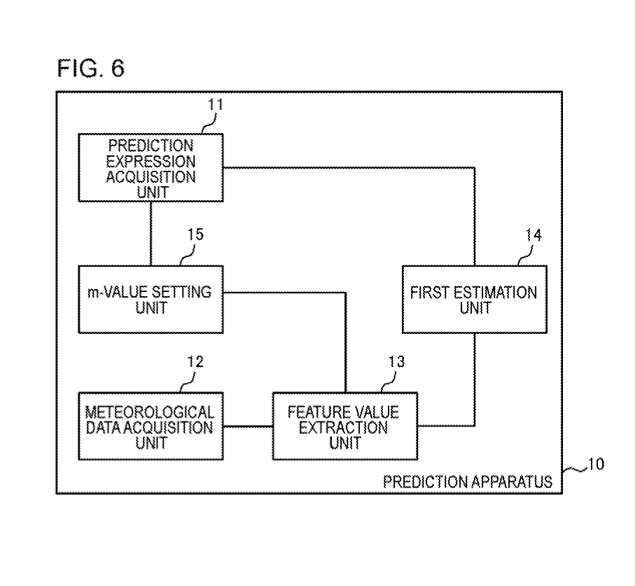

FIG. 6 shows an example of a functional block diagram of the prediction apparatus 10 of the present exemplary embodiment. As illustrated, the prediction apparatus 10 includes a prediction expression acquisition unit 11, a meteorological data acquisition unit 12, a feature value extraction unit 13, a first estimation unit 14, and an m-value setting unit 15. Hereinafter, a difference from the first and second exemplary embodiments will be described.

The m-value setting unit 15 sets the value of m. For example, the m-value setting unit 15 may determine the optimum value of m by analysis using past data and set the determined value. For example, the m-value setting unit 15 may calculate the accuracy of estimation for each value of m by the above analysis. Then, the m-value setting unit 15 may set the value of m with the highest accuracy. In addition, the m-value setting unit 15 may receive input specifying the value of m from the user. Then, the m-value setting unit 15 may set the received value. For example, the m-value setting unit 15 may include a unit that outputs the result of the above analysis (accuracy of estimation for each value of m) to the user, and a unit that receives an input specifying the value of m from the user.

The prediction expression acquisition unit 11 acquires the prediction expression generated based on the value of m set by the m-value setting unit 15. The feature value extraction unit 13 extracts a feature value based on the value of m that is set by the m-value setting unit 15.

Here, an example of a process executed by the m-value setting unit 15 for calculating the accuracy of estimation for each value of m by analysis using past data will be described. Here, a process of determining the value of m suitable for estimation at the first target time will be described.

(1) First, the m-value setting unit 15 extracts, from the past data stored in the past data storage unit 21, data (hereinafter, referred to as target data) used for generating a prediction expression by the prediction expression generation unit 22.

The target data may be, for example, data having a predetermined attribute similar to that of the prediction target at a predetermined level or more (example: data of which an observation site matches, data of which season matches, data of which the month of the prediction target day matches, data of which the meteorological data of a predetermined item is similar at a predetermined level or more, or the like), or may be data from predetermined days before the prediction target day to the day before the prediction target day.

(2) Next, the m-value setting unit 15 generates a prediction expression (a prediction expression for prediction at the first target time) corresponding to each of plural values of m (example: 1 to 15), based on the target data.

(3) Thereafter, them-value setting unit 15 inputs a feature value of any sample day in the target data (feature value extracted from meteorological data from m hours before the first target time to the first target time), to each prediction expression generated for each value of m, and obtains the prediction value of a natural energy power generation amount, a solar radiation amount, or a wind speed at the first target time on the sample day.

(4) Thereafter, for each value of m, the m-value setting unit 15 calculates a difference between the actual value at the first target time of the sample day and the prediction value at the first target time of the sample day calculated in the above (3).

Note that, any plural sample days may be set, and the processes of (3) and (4) may be performed at each of the sample days. In this way, plural differences are obtained for each value of m. In this case, the m-value setting unit 15 may set a statistical value (example: an average value, a maximum value, a minimum value, a mode, a median value, or the like) of the plural differences as a representative value of the difference for each value of m.

Based on the differences obtained in this manner, the accuracy of estimation for each value of m in the estimation at the first target time can be evaluated. This means that the smaller the difference, the higher the accuracy of prediction. For example, the m-value setting unit 15 may set the value of m with the smallest difference. Note that, the m-value setting unit 15 may execute the above process at each target time to set an optimum value of m.

Further, as shown in the following example, the present inventors have found that the optimum value of m for improving the accuracy of prediction may be different if the attribute (an observation point, season, month, weather, or the like) of a prediction target is different.

For example, the phenomenon can occur in which the accuracy of prediction is the highest when the value of m is 10 at a certain observation point, and the accuracy of prediction is the highest when the value of m is 12 at another observation point. Similarly, the optimum value of m can change depending on season, month, weather, or the like.

According to the present exemplary embodiment, the m-value setting unit 15 can select appropriate target data according to the estimation target, and set the optimum value of m for each observation site (for each region). That is, an estimation expression optimized for each observation site can be used. Further, the m-value setting unit 15 can set an optimum value of m for each prediction target day, based on the attribute (season, month, weather, or the like) of the prediction target day. That is, an estimation expression optimized for each prediction target day can be used. According to the present exemplary embodiment, the accuracy of estimation of a natural energy power generation amount, a solar radiation amount, or a wind speed is improved.

Depending on the use of the estimated natural energy power generation amount, solar radiation amount, or wind speed, a certain degree of accuracy of estimation may be acceptable, or it may be desired to improve the processing speed of estimation rather than the accuracy of estimation. According to the present exemplary embodiment in which the user can specify the value of m, the user can select, for example, the value of m suitable for its use, in consideration of the accuracy of estimation for each value of m provided by the prediction apparatus 10. For example, in a case where the accuracy of estimation is emphasized, the user can select the optimum value of m (a value that can improve the accuracy of estimation) even if the processing speed becomes slow. Further, in a case where the processing speed is emphasized, it is possible to select any value of m by which a certain degree of accuracy of estimation can be obtained. As described above, according to the prediction apparatus 10 of the present exemplary embodiment, a user-friendly apparatus can be realized.

### Fourth Exemplary Embodiment

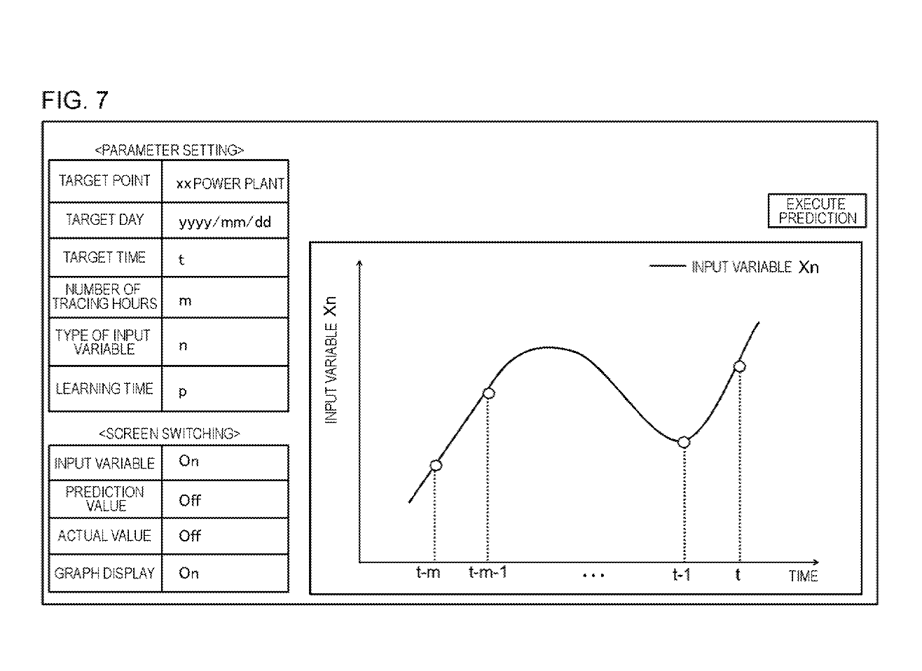

The prediction apparatus 10 of the present exemplary embodiment is different from the first to third exemplary embodiments in that it includes a unit (information output unit) that provides predetermined information to the user. FIG. 7 to FIG. 9 show an example of information output by the information output unit of the present exemplary embodiment.

In the example shown in FIG. 7, an area (parameter setting area) for displaying the set parameter, a main area for displaying predetermined main information (in the case of FIG. 7, an area in which a graph showing the time variation of the input variable Xn is displayed), and an area (a screen switching area) for displaying selection details of information displayed in the main area are displayed.

Various set parameters are displayed in the parameter setting area. In the case of the examples of the drawings, the target point (observation site), the target day (prediction target day), the target time, the setting value of the tracing time (the setting value of m), the type (one or plural items of meteorological data) of an input variable (explanatory variable), the number of learning days (the amount of training data used to generate a prediction expression) are shown.

In the screen switching area, the selection details of the information to be displayed in the main area is displayed. There are parameters of an input variable, a prediction value, an actual value, and a graph display in the area and each is associated with On or Off.

In the case of the example of FIG. 7 in which the input variable and the graph display are On and the prediction value and the actual value are Off, a graph representing the set input variable on one axis and time on the other axis is displayed in the main area. The feature value (input variable) extracted from meteorological data (meteorological data of the item set as the input variable) from m hours before the target time (t), (t−m), to the target time (t) on the prediction target day is displayed on the graph. Note that, if there are plural types of input variables (the item of meteorological data) that are set, the graphs as shown in the drawing may be displayed side by side.

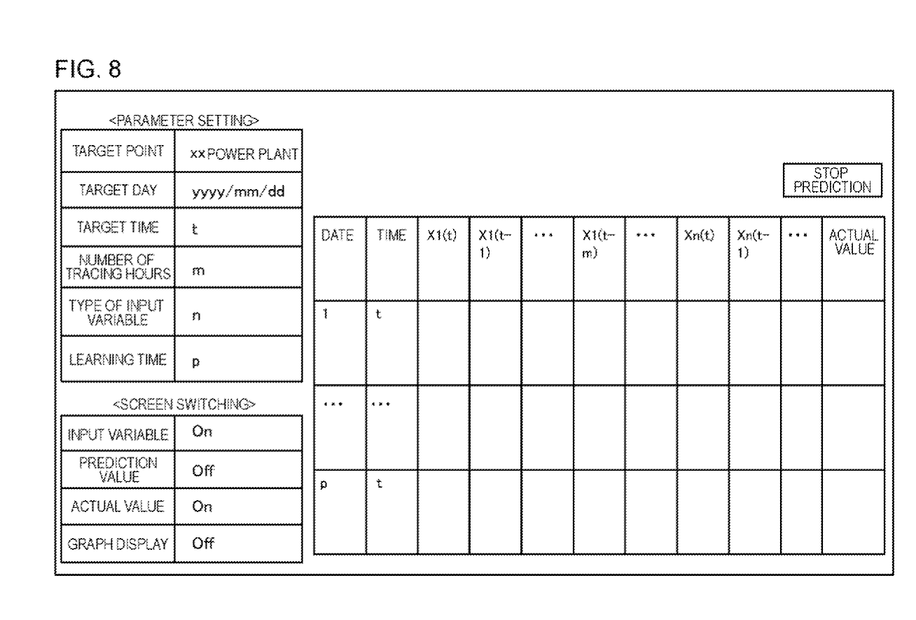

The structure of the information of the example shown in FIG. 8 is the same as in FIG. 7. In the case of the example shown in FIG. 8, when observing the screen switching area, the input variable and the actual value are On, and the prediction value and the graph display are Off. In the example, the values of training data used for generating the prediction expression are listed in the main area. It is known from the drawing that training data for p days is displayed, explanatory variables (X1(t) . . . ) and objective variables (actual values at target time (t) (a natural energy power generation amount, a solar radiation amount, or a wind speed)) are displayed.

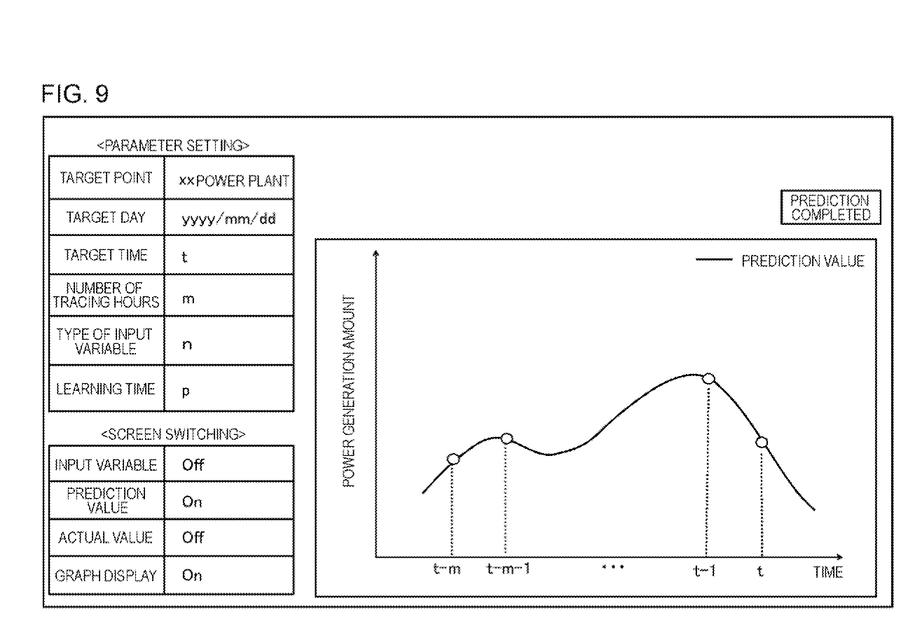

The structure of the information of the example shown in FIG. 9 is the same as in FIG. 7 and FIG. 8. In the case of the example shown in FIG. 9, when observing the screen switching area, the prediction value and the graph display are On, and the input variable and the actual value are Off. In the case of the example, a graph representing a natural energy power generation amount (an actual value and a prediction value) on one axis and time on the other axis is displayed in the main area. The values of the natural energy power generation amount (the actual value and the prediction value) up to the target time (t) on the prediction target day are displayed on the graph. For example, the prediction value estimated by the first estimation unit 14 may be displayed at all points of times on the graph. In addition, the actual value may be plotted at the time when the actual value of a natural energy power generation amount has been obtained by the time of graph display. Then, the prediction value estimated by the first estimation unit 14 may be displayed at the time when the actual value has not been obtained.

As described in the third exemplary embodiment, the m-value setting unit 15 may include a unit that outputs the result of the above analysis (accuracy of estimation for each value of m) to the user, and a unit that receives an input specifying the value of m from the user. For example, the m-value setting unit 15 may display the result of the above analysis on the screen (for example, a main area) as shown in FIG. 7 to FIG. 9. Then, the m-value setting unit 15 may display a graphical user interface (GUI) component which receives an input specifying the value of m on a screen (for example, a parameter setting area) as shown in FIG. 7 to FIG. 9, and receive the input of the value of m.

The m-value setting unit 15 sets the value of m. For example, the m-value setting unit 15 may determine the optimum value of m by analysis using past data and set the determined value. For example, the m-value setting unit 15 may calculate the accuracy of estimation for each value of m by the above analysis. Then, the m-value setting unit 15 may set the value of m with the highest accuracy. In addition, the m-value setting unit 15 may receive input specifying the value of m from the user. Then, the m-value setting unit 15 may set the received value. For example, the m-value setting unit 15 may include a unit that outputs the result of the above analysis (accuracy of estimation for each value of m) to the user, and a unit that receives an input specifying the value of m from the user.

According to the present exemplary embodiment described above, details of an input variable used for estimation, details of training data used for an estimation expression, and an estimation result can be output to the user in a predetermined display format. According to the present exemplary embodiment, the user can determine the validity of the estimation result by checking not only the estimation result but also details of the input variable and the training data.

### Fifth Exemplary Embodiment

The prediction apparatus 30 of the present exemplary embodiment estimates a natural energy power generation amount, a solar radiation amount, or a wind speed at the target time on the prediction target day, by machine learning based on the actual data (the natural energy power generation amount, the solar radiation amount, or the wind speed) from n (n is greater than 0) hours before the target time to predetermined hours (hours shorter than n) before the target time on the prediction target day. The value of n is variable. This will be described in detail below.

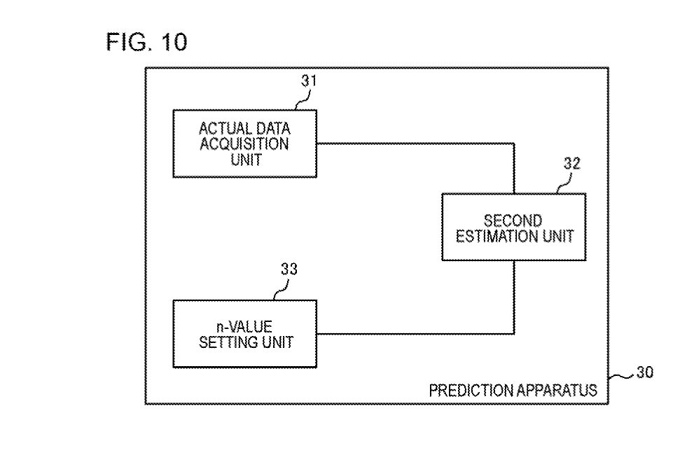

FIG. 10 shows an example of a functional block diagram of the prediction apparatus 30 of the present exemplary embodiment. As illustrated, the prediction apparatus 30 includes an actual data acquisition unit 31, a second estimation unit 32, and an n-value setting unit 33.

The actual data acquisition unit 31 acquires actual data of the natural energy power generation amount, the solar radiation amount, or the wind speed up to predetermined hours before the target time on the prediction target day. The actual data acquisition unit 31 acquires, at least, actual data of the natural energy power generation amount, the solar radiation amount, or the wind speed from n (n is greater than 0) hours before the target time to predetermined hours (hours shorter than n) before the target time on the prediction target day.

The second estimation unit 32 estimates a natural energy power generation amount, a solar radiation amount, or a wind speed at the target time, based on the actual data (the natural energy power generation amount, the solar radiation amount, or the wind speed) from n (n is greater than 0) hours before the target time to predetermined hours (hours shorter than n) before the target time. For example, a model for time series analysis may be used for the estimation.

The n-value setting unit 33 sets an n-value. For example, the n-value setting unit 33 may calculate the accuracy of estimation (estimation by the second estimation unit 32) for each value of n, by analysis using the past data stored in the past data storage unit 21. Then, the n-value setting unit 33 may determine the value of n based on the calculation result, and set the determined value. For example, the n-value setting unit 33 may set the value of n with the highest accuracy. In addition, the n-value setting unit 33 may receive an input specifying the value of n from the user. Then, the n-value setting unit 33 may set the received value. For example, the n-value setting unit 33 may include a unit that outputs the result of the above analysis (accuracy of estimation for each value of n) to the user, and a unit that receives an input specifying the value of n from the user.

Here, an example of analysis using past data performed by the n-value setting unit 33 will be described. Here, a process of determining an n-value suitable for estimation at the first target time will be described.

(1)′ First, the n-value setting unit 33 extracts predetermined data, from the past data stored in the past data storage unit 21. For example, the prediction apparatus 30 may include the past data storage unit 21. Alternatively, an external apparatus that is communicable with the prediction apparatus 30 may include the past data storage unit 21.

The n-value setting unit 33 may extract, for example, data having a predetermined attribute similar to that of a prediction target in which at least one of a prediction target day and an observation site is specified at a predetermined level or more (example: data of which an observation site matches, data of which season matches, data of which the month of the prediction target day matches, data of which the meteorological data of a predetermined item is similar at a predetermined level or more, or the like), or may extract data from predetermined days before the prediction target day to the day before the prediction target day.

(2)′ Thereafter, the n-value setting unit 33 performs prediction of a natural energy power generation amount, a solar radiation amount, or a wind speed at a first target time, based on the actual data (the natural energy power generation amount, the solar radiation amount, or the wind speed) from n (n is greater than 0) hours before the first target time to predetermined hours (hours shorter than n) before the first target time, by using the extracted data. The same algorithm as that used by the second estimation unit 32 is used for prediction here.

(3)′ Thereafter, the n-value setting unit 33 calculates a difference between the calculated prediction value at the first target time and the actual value at the first target time. Note that, the above difference for each day may be calculated based on data for each of plural days. The statistical value (example: an average value, a maximum value, a minimum value, a mode, a median value, or the like) may be calculated as a representative value of the differences.

The n-value setting unit 33 performs the processes of the above (2)′ and (3)′ for each of plural values of n, and calculates the difference for each value of n. The accuracy of estimation of each value of n can be evaluated, based on the difference. This means that the smaller the difference, the higher the accuracy of prediction. For example, the n-value setting unit 33 may set the value of n with the smallest difference.

The second estimation unit 32 estimates a natural energy power generation amount, a solar radiation amount, or a wind speed based on the value of n set by the n-value setting unit 33.

As described above, the prediction apparatus 30 of the present exemplary embodiment estimates a natural energy power generation amount, a solar radiation amount, or a wind speed at the target time on the prediction target day, by machine learning based on the actual data (the natural energy power generation amount, the solar radiation amount, or the wind speed) from n (n is greater than 0) hours before the target time to predetermined hours (hours shorter than n) before the target time on the prediction target day.

The value of n is variable. According to the prediction apparatus 30 of the present exemplary embodiment, for example, it is possible to determine an optimum value of n for each observation site, or determine an optimum value of n for each predetermined attribute (season, month, weather, or the like), by selecting the optimum data in the process of the above (1)′. According to the present exemplary embodiment, the accuracy of estimation of a natural energy power generation amount, a solar radiation amount, or a wind speed is improved.

### Example

The prediction apparatuses 10 of the first to fourth exemplary embodiments are verified under the following conditions.

Observation site: Sapporo, Tokyo

Prediction target day: Each day from June to August 2008

Target time: 8 o'clock, 9 o'clock, 10 o'clock, 11 o'clock, 12 o'clock, 13 o'clock, 14 o'clock, 15 o'clock, o'clock and 17 o'clock

The value of m: 0 to 12 each

Training data: Data for 60 days immediately before prediction target day

Explanatory variable: values every hour of an upper cloud amount, a middle cloud amount, a lower cloud amount, temperature, and humidity from m hours before a target time to the target time, and values every hour of an extraterrestrial solar radiation amount at the target time and one hour before the target time.

Objective variable: solar radiation amount of target time

Value to be entered to the estimation expression: prediction values every hour of meteorological data (item of the explanatory variable) from m hours before the target time to the target time on a prediction target day which is announced at 15 o'clock on the day before the prediction target day

Prediction execution time: the prediction of the next day is performed at 18 o'clock on the day before the prediction target day

Machine learning method: support vector machine

“Accuracy improvement rate according to the value of m”

First, a prediction error of each value of m is calculated using a mean absolute percentage error (MAPE). xi is the actual value of a solar radiation amount at each target time. yi is an estimated value of the solar radiation amount at each target time estimated under the above conditions. n is the number of samples corresponding to each of the values of m.

$$MAPE = \frac{{\sum }_{i = 1}^{n} \vert {x}_{i} - {y}_{i} \vert}{n \cdot {max}_{1 \leq i \leq n} ( {x}_{i} )}$$

Then, the accuracy improvement rate of each value of m is set as the difference obtained by subtracting an MAPE value of each value of m from a reference value, with the MAPE value at the time of m=0 as the reference value. In a case where the accuracy improvement rate is a positive value, the accuracy is improved compared to the case where m=0. The accuracy is improved as the value is increased. On the other hand, in a case where the accuracy improvement rate is a negative value, the accuracy is deteriorated compared to the case where m=0. The accuracy is deteriorated as the value is decreased.

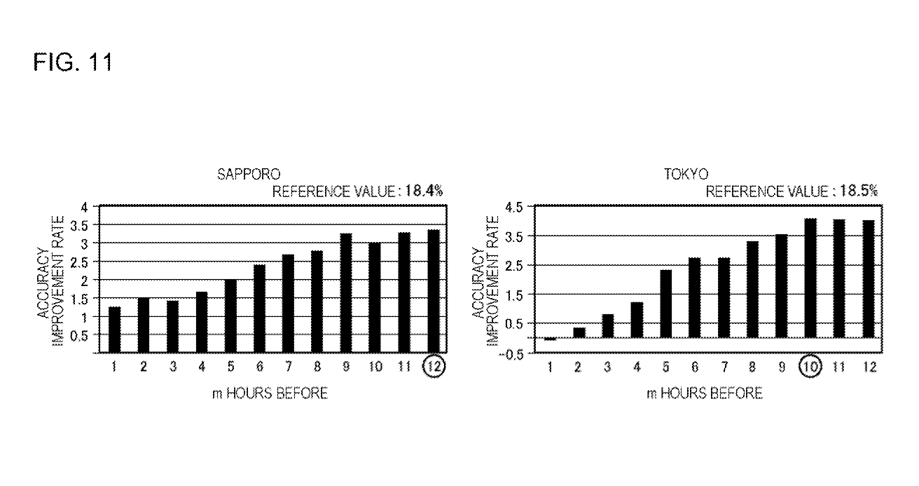

FIG. 11 shows the verification result in each of Sapporo and Tokyo. The reference value shown in the drawing indicates the MAPE value in the case of m=0. From the drawing, even in both Sapporo and Tokyo, it is shown that the accuracy improvement rate is higher in the case where the value of m is 2 or more than in the case where the value of m is 1. Even in both Sapporo and Tokyo, in a case where the value of m is the predetermined value or less, it is shown that the accuracy improvement rate tends to increase as the value of m increases.

Further, it is shown that if the value of m exceeds a predetermined value, the accuracy improvement rate reaches a plateau, and even if the value of m increases further, it does not change too much. Then, the value of m at which the accuracy improvement rate reaches a plateau is found to be different for each observation site.

Moreover, it is shown that the value of m with the highest accuracy improvement rate in Sapporo is 12 and the value of m with the highest accuracy improvement rate in Tokyo is 10. That is, it is shown that the optimum value of m varies at each observation site.

Examples of reference configurations will be added below.

1. A prediction apparatus including:

a prediction expression acquisition unit that acquires a prediction expression for predicting a natural energy power generation amount, a solar radiation amount, or a wind speed at a target time which is generated by machine learning based on training data over plural days with a feature value extracted from meteorological data from m (m is 2 or more) hours before the target time to the target time as an explanatory variable, and the natural energy power generation amount, the solar radiation amount, or the wind speed at the target time as an objective variable;

a meteorological data acquisition unit that acquires meteorological data up to the target time on a prediction target day;

a feature value extraction unit that extracts the feature value from meteorological data from m hours before the target time to the target time on the prediction target day; and

a first estimation unit that estimates a natural energy power generation amount, a solar radiation amount, or a wind speed at the target time on the prediction target day, based on the prediction expression acquired by the prediction expression acquisition unit and the feature value extracted by the feature value extraction unit.

2. The prediction apparatus according to 1, further including

an m-value setting unit that sets a value of m,

in which the value of m is variable.

3. The prediction apparatus according to 2,

in which the first estimation unit estimates natural energy power generation amounts, solar radiation amounts, or wind speeds in plural regions, and

in which the m-value setting unit sets the value of m for each region.

4. The prediction apparatus according to 2 or 3,

in which the m-value setting unit sets the value of m, based on the attribute of the prediction target day.

5. The prediction apparatus according to any one of 1 to 4,

in which the prediction expression acquisition unit acquires a prediction expression generated based on the training data having a predetermined attribute similar to that of a prediction target in which at least one of a prediction target day and a prediction target point is specified, at a predetermined level or more.

6. The prediction apparatus according to any one of 1 to 5,

in which the feature value indicates the feature of a variation of meteorological data within a period of time from m hours before the target time to the target time.

7. A prediction method executed by a computer, the method comprising:

a prediction expression acquisition step of acquiring a prediction expression for predicting a natural energy power generation amount, a solar radiation amount, or a wind speed at a target time which is generated by machine learning based on training data over plural days with a feature value extracted from meteorological data from m (m is 2 or more) hours before the target time to the target time as an explanatory variable, and the natural energy power generation amount, the solar radiation amount, or the wind speed at the target time as an objective variable;

a meteorological data acquisition step of acquiring meteorological data up to the target time on a prediction target day;

a feature value extraction step of extracting the feature value from meteorological data from m hours before the target time to the target time on the prediction target day; and

a first estimation step of estimating a natural energy power generation amount, a solar radiation amount, or a wind speed at the target time on the prediction target day, based on the prediction expression acquired in the prediction expression acquisition step and the feature value extracted in the feature value extraction step.

8. A program causing a computer to function as:

a prediction expression acquisition unit that acquires a prediction expression for predicting a natural energy power generation amount, a solar radiation amount, or a wind speed at a target time which is generated by machine learning based on training data over plural days with a feature value extracted from meteorological data from m (m is 2 or more) hours before the target time to the target time as an explanatory variable, and the natural energy power generation amount, the solar radiation amount, or the wind speed at the target time as an objective variable;

a meteorological data acquisition unit that acquires meteorological data up to the target time on a prediction target day;

a feature value extraction unit that extracts the feature value from meteorological data from m hours before the target time to the target time on the prediction target day; and

a first estimation unit that estimates a natural energy power generation amount, a solar radiation amount, or a wind speed at the target time on the prediction target day, based on the prediction expression acquired by the prediction expression acquisition unit and the feature value extracted by the feature value extraction unit.

9. A prediction apparatus including:

an actual data acquisition unit that acquires actual data of a natural energy power generation amount, a solar radiation amount, or a wind speed up to predetermined hours before a target time on a prediction target day;

a second estimation unit that estimates a natural energy power generation amount, a solar radiation amount, or a wind speed at the target time, based on the actual data from n (n is greater than 0) hours before the target time to the predetermined hours before the target time; and

an n-value setting unit that sets a value of n, in which the value of n is variable.

10. A prediction method executed by a computer, the method including:

an actual data acquisition step of acquiring actual data of a natural energy power generation amount, a solar radiation amount, or a wind speed up to predetermined hours before a target time on a prediction target day;

a second estimation step of estimating a natural energy power generation amount, a solar radiation amount, or a wind speed at the target time, based on the actual data from n (n is greater than 0) hours before the target time to the predetermined hours before the target time; and

an n-value setting step of setting a value of n, in which the value of n is variable.

11. A program causing a computer to function as:

an actual data acquisition unit that acquires actual data of a natural energy power generation amount, a solar radiation amount, or a wind speed up to predetermined hours before a target time on a prediction target day;

a second estimation unit that estimates a natural energy power generation amount, a solar radiation amount, or a wind speed at the target time, based on the actual data from n (n is greater than 0) hours before the target time to the predetermined hours before the target time; and

an n-value setting unit that sets a value of n, in which the value of n is variable.

This application claims priority based on Japanese Patent Application No. 2015-017107 filed on Jan. 30, 2015, and the disclosure of which is incorporated herein in its entirety.

1. A prediction apparatus comprising:
a feature value extraction unit that extracts a feature value being a variation in time series from meteorological data from m (m is 2 or more) hours before a target time to the target time; and
an estimation unit that estimates a natural energy power generation amount, a solar radiation amount, or a wind speed at the target time based on the feature values over a plurality of days.

2. The prediction apparatus according to claim 1,
wherein the estimation unit performs estimation by using a prediction expression for performing prediction with the feature value extracted from meteorological data up to the target time as an explanatory variable, and the natural energy power generation amount, the solar radiation amount, or the wind speed at the target time as an objective variable.

3. The prediction apparatus according to claim 2,
wherein the estimation unit performs estimation by using a prediction expression based on training data over a plurality of days comprising a combination of the explanatory variable and the objective variable.

4. The prediction apparatus according to claim 1,
wherein the estimation unit performs estimation based on the feature values over a plurality of days, the feature values being similar to that of the prediction target day in a predetermined attribute.

5. The prediction apparatus according to claim 1, further comprising:
an m-value setting unit that sets a value of m,
wherein the value of m is variable.

6. The prediction apparatus according to claim 5,
wherein the estimation unit estimates natural energy power generation amounts, solar radiation amounts, or wind speeds in a plurality of regions, and
wherein the m-value setting unit sets the value of m for each region.

7. The prediction apparatus according to claim 5,
wherein the m-value setting unit sets the value of m, based on an attribute of the prediction target day.

8. The prediction apparatus according to claim 5,
wherein the m-value setting unit includes a unit that outputs the accuracy of estimation for each value of m.

9. The prediction apparatus according to claim 1,
wherein the estimation unit performs estimation by using the prediction expression generated based on training data having a predetermined attribute similar to that of a prediction target in which at least one of a prediction target day and a prediction target point is specified, at a predetermined level or more.

10. A prediction apparatus comprising:
a feature value extraction unit that extracts a feature value being a variation in time series from meteorological data from m (m is 2 or more) hours before a target time to the target time; and
an estimation unit that estimates a natural energy power generation amount, a solar radiation amount, or a wind speed at the target time based on the feature value.

11. A prediction apparatus comprising:
a prediction expression acquisition unit that acquires a prediction expression for predicting a natural energy power generation amount, a solar radiation amount, or a wind speed at a target time which is generated by machine learning based on training data over a plurality of days with a feature value extracted from meteorological data from m (m is 2 or more) hours before the target time to the target time as an explanatory variable, and the natural energy power generation amount, the solar radiation amount, or the wind speed at the target time as an objective variable;
a meteorological data acquisition unit that acquires meteorological data up to the target time on a prediction target day;
a feature value extraction unit that extracts the feature value from meteorological data from m hours before the target time to the target time on the prediction target day; and
a first estimation unit that estimates a natural energy power generation amount, a solar radiation amount, or a wind speed at the target time on the prediction target day, based on the prediction expression acquired by the prediction expression acquisition unit and the feature value extracted by the feature value extraction unit.

12. A prediction method executed by a computer, the method comprising:
a feature value extraction step of extracting a feature value being a variation in time series from meteorological data from m (m is 2 or more) hours before a target time to the target time; and
an estimation step of estimating a natural energy power generation amount, a solar radiation amount, or a wind speed at the target time based on the feature values over a plurality of days.

13. A non-transitory storage medium storing a program causing a computer to function as:
a feature value extraction unit that extracts a feature value having a variation in time series from meteorological data from m (m is 2 or more) hours before a target time to the target time; and
an estimation unit that estimates a natural energy power generation amount, a solar radiation amount, or a wind speed at the target time based on the feature values over a plurality of days.
